(19) United States
(12) Patent Application Publication
(10) Pub. No.: US 2022/0168866 A1
(43) Pub. Date: Jun. 2, 2022

(54) SUBSTRATE PROCESSING APPARATUS AND SUBSTRATE PROCESSING METHOD USING PHOTOCATALYST

(71) Applicant: EBARA CORPORATION, Tokyo (JP)

(72) Inventors: Erina Baba, Tokyo (JP); Itsuki Kobata, Tokyo (JP)

(21) Appl. No.: 17/432,284

(22) PCT Filed: Jan. 8, 2020
(86) PCT No.: PCT/JP2020/000263

§ 371 Date: Aug. 19, 2021

(30) Foreign Application Priority Data
Mar. 8, 2019 (JP) 2019-042511

(51) Int. Cl. B24B 37/20; B24B 57/02; B24B 53/017; B01J 35/00

(52) U.S. Cl. CPC B24B 37/20; B01J 35/004; B24B 53/017; B24B 57/02

(57) ABSTRACT

Provided is an apparatus and a method that allow a control of a removal amount at an atomic level and allow a selective removal from a projecting portion of a process target.

According to one embodiment, a substrate processing apparatus is provided, and the substrate processing apparatus includes: a table for holding a substrate; a nozzle for supplying a process liquid to a top of the substrate held onto the table; a head for holding a photocatalyst; a conditioner for conditioning the photocatalyst; a first moving mechanism for moving the head in a direction perpendicular to a surface of the table; and a second moving mechanism for moving the head between the table and the conditioner.

### TECHNICAL FIELD

This application relates to a substrate processing apparatus and a substrate processing method using a photocatalyst. This application claims priority from Japanese Patent Application No. 2019-042511 filed on Mar. 8, 2019. The entire disclosure including the descriptions, the claims, the drawings, and the abstracts in Japanese Patent Application No. 2019-042511 is herein incorporated by reference.

### BACKGROUND ART

There has been known Chemical Mechanical Polishing (CMP) as a technique for planarizing a substrate. Generally, in CMP, a process target and a polishing pad are relatively moved while pressing the process target such as a semiconductor substrate against the polishing pad and supplying an abrasive (slurry) between the process target and the polishing pad, thereby polishing a surface of the process target.

There has been known that a polishing rate in a CMP apparatus follows Preston's law, and the polishing rate is proportionate to a pressing force to a process target of a polishing pad. Since a projecting portion of a surface of the process target receives a larger pressure than a depressed portion, the polishing rate is higher in the projecting portion than the depressed portion. In the CMP apparatus, a level difference present in the process target is removed by the difference in polishing rate between the projecting portion and the depressed portion, thus ensuring the planarization.

### CITATION LIST

### Patent Literature

PTL 1: Japanese Unexamined Patent Application Publication (Translation of PCT Application) No. 2013-538169

PTL 2: Japanese Patent No. 4904506

PTL 3: Japanese Unexamined Patent Application Publication No. 2002-334856

PTL 4: Japanese Unexamined Patent Application Publication No. 2015-128161

### SUMMARY OF INVENTION

### Technical Problem

Now, recently, the miniaturization of semiconductor has been advanced more and more, and desired accuracies of respective processes have already reached orders of several nm. The controllability at the atomic level is further required in the future. The planarization process typified by the CMP is no exception, and the controllability at the atomic level is required under the situation that the removal amount itself is decreased to, for example, about 100 Å in association with the miniaturization. To satisfy this request, polishing and cleaning conditions are optimized in the CMP.

However, since the removal mechanism in CMP is macro and has variation, it is possibly difficult to control the removal amount at the atomic level. For example, in the attempt to ensure the removal amount control at the atomic level of about A by CMP, the polishing rate itself requires to be significantly decreased compared with the ordinary polishing, and therefore, it is necessary to set a polishing pressure to an extremely low pressure, or to decrease a relative velocity between a substrate and a polishing pad. When the polishing rate is small, since the variation in polishing rate cannot be ignored, it is also necessary to control various factors that affect the polishing rate, for example, a surface temperature of the polishing pad and a slurry supply amount. However, since these factors complicatedly affect one another, and a control variation of a component and a temporal change of a consumable material also have the influences, it is considered to be difficult to ensure the perfect control by these factors.

Therefore, the present disclosure has one object to provide an apparatus and a method that include a removal mechanism and a control factor different from a CMP to allow a control of a removal amount at an atomic level and allow a selective removal from a projecting portion of a process target.

### Solution to Problem

According to one embodiment, a substrate processing apparatus is provided, and the substrate processing apparatus includes: a table for holding a substrate; a nozzle for supplying a process liquid to a top of the substrate held onto the table; a head for holding a photocatalyst; a conditioner for conditioning the photocatalyst; a first moving mechanism for moving the head in a direction perpendicular to a surface of the table; and a second moving mechanism for moving the head between the table and the conditioner.

### BRIEF DESCRIPTION OF DRAWINGS

FIG. 1A is a perspective view illustrating a schematic configuration of a substrate processing apparatus according to one embodiment.

FIG. 1B is a top view schematically illustrating the substrate processing apparatus illustrated in FIG. 1A.

FIG. 1C is a side view schematically illustrating the substrate processing apparatus illustrated in FIG. 1A.

FIG. 1D is a side view schematically illustrating a state of performing a conditioning to a photocatalyst according to the one embodiment.

FIG. 2 is a side view schematically illustrating a substrate processing apparatus according to one embodiment.

FIG. 3A is a side view schematically illustrating a substrate processing apparatus according to one embodiment.

FIG. 3B is a top view schematically illustrating the substrate processing apparatus illustrated in FIG. 3A.

FIG. 4A is a side view schematically illustrating a substrate processing apparatus according to one embodiment.

FIG. 4B is a top view schematically illustrating the substrate processing apparatus illustrated in FIG. 4A.

FIG. 5 is a side view schematically illustrating a substrate processing apparatus according to one embodiment.

FIG. 6 is a block diagram schematically illustrating a substrate processing system according to one embodiment.

FIG. 7 is a flowchart illustrating a substrate processing method according to one embodiment.

FIG. 8 is a flowchart illustrating a substrate processing method according to one embodiment.

### DESCRIPTION OF EMBODIMENTS

The following describes a substrate processing apparatus and a substrate processing method using a photocatalyst according to the present invention with the attached drawings. In the attached drawings, identical or similar reference numerals are attached to identical or similar components, and overlapping description regarding the identical or similar components may be omitted in the description of the respective embodiments. Features illustrated in the respective embodiments are applicable to other embodiments in so far as they are consistent with one another. In this description, a “substrate” includes a magnetic recording medium, a magnetic recording sensor, a mirror, an optical element, a micro mechanical element, or a partially fabricated integrated circuit, not only a semiconductor substrate, a glass substrate, or a printed circuit board.

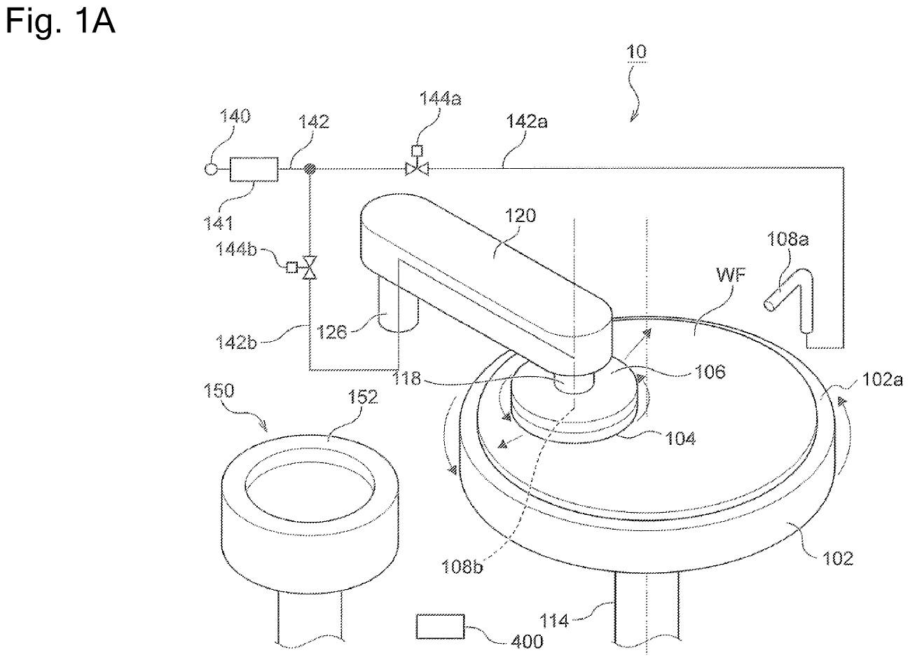

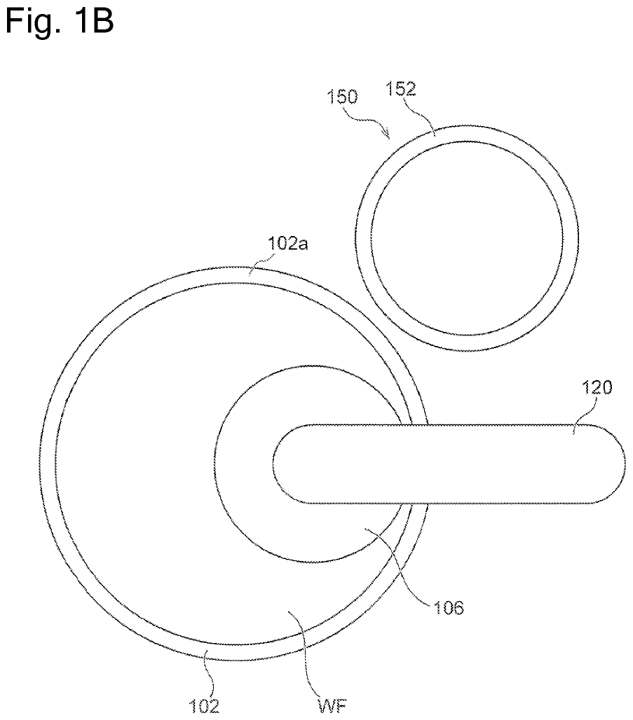

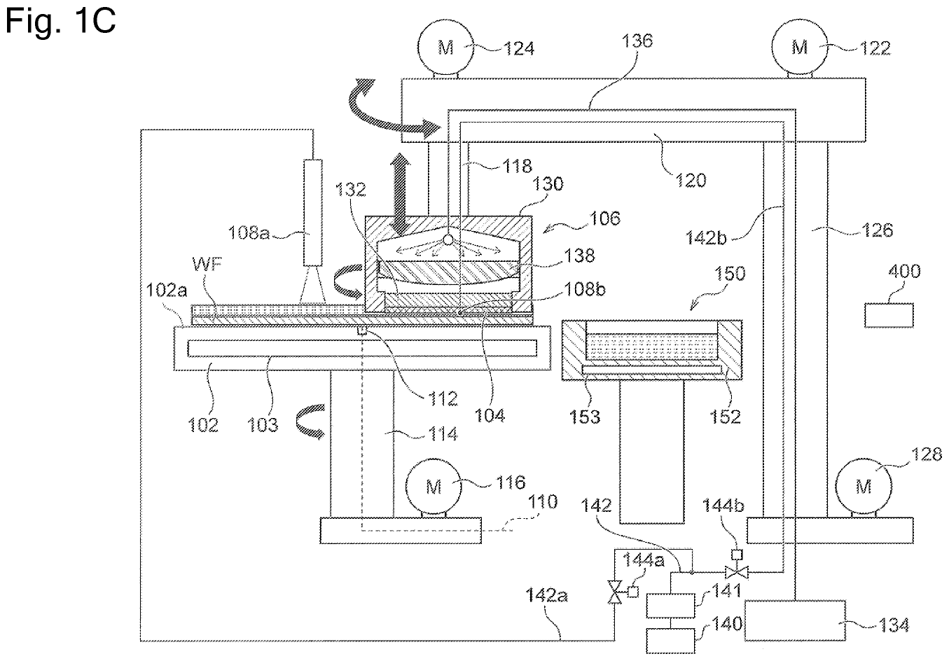

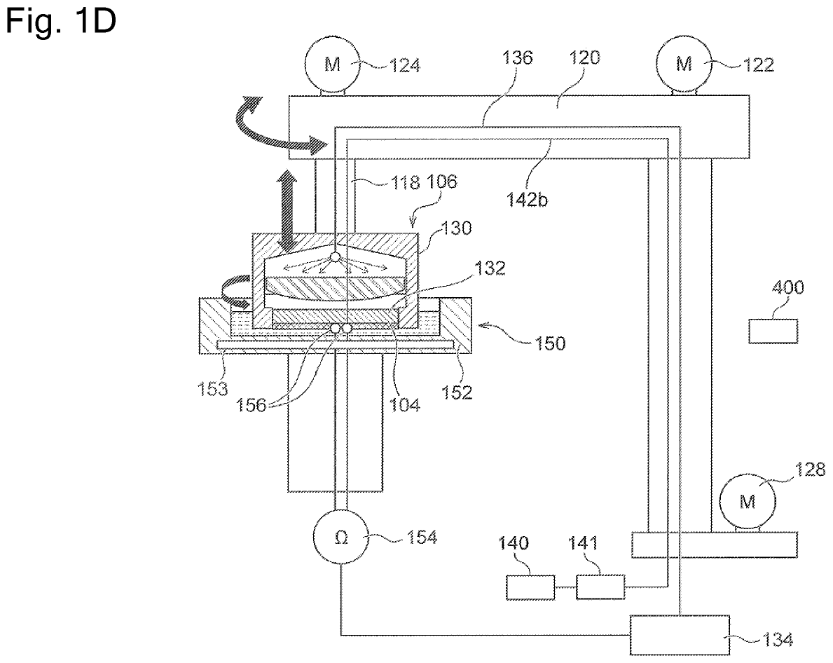

FIG. 1 illustrates a schematic configuration of a substrate processing apparatus according to one embodiment. FIG. 1A is a perspective view illustrating a schematic configuration of the substrate processing apparatus according to the one embodiment. FIG. 1B is a top view schematically illustrating the substrate processing apparatus illustrated in FIG. 1A. FIG. 1C is a side view schematically illustrating the substrate processing apparatus illustrated in FIG. 1A. FIG. 1C partially illustrates a cross-sectional surface. The substrate processing apparatus illustrated in FIG. 1 can be configured as a part of a substrate processing system or one unit in the substrate processing system that includes a CMP apparatus, which performs a polishing process of a substrate such as a semiconductor wafer, a cleaning device, and the like.

As illustrated in FIG. 1, a substrate processing apparatus 10 according to one embodiment includes a table 102 configured to hold a substrate WF, a head 106 for holding a photocatalyst 104 for processing a surface to be processed of the substrate WF, a nozzle 108 for supplying a process liquid a conditioner 150 for performing a conditioning of the photocatalyst 104, and a controller 400.

The controller 400 can include a common general-purpose computer, a dedicated computer, or the like. The components described later of the substrate processing apparatus 10 can be configured to be each controlled by the controller 400.

The table 102 includes a support surface 102a for holding the substrate WF. The support surface 102a is provided with an opening portion 112 of a passage 110 (see FIG. 1C) used for suctioning the substrate WF. The passage 110 is connected to a vacuum source (not illustrated), and can vacuum-suction the substrate WF. The substrate WF may be suctioned to the table 102 via a backing material. The backing material can be formed of, for example, a foamed polyurethane with elasticity. The table 102 is coupled to a drive shaft 114. The drive shaft 114 is configured to be rotatable by a drive mechanism such as a motor 116 and a drive belt. Therefore, the table 102 is configured to be rotatable.

In one embodiment, the table 102 can include a temperature controller 103 (see FIG. 1C). In one embodiment, the temperature controller 103 can include a heating element, such as a heating wire, and a cooling element, such as a Peltier element, which are disposed in the table 102. In one embodiment, the temperature controller 103 can be configured to flow a fluid (for example, water) at a controlled temperature to a fluid passage formed in the table 102. The temperature of the substrate WF arranged on the table 102 can be controlled by the temperature controller 103.

As illustrated in FIG. 1, the head 106 is connected to a rotatable shaft 118. The shaft 118 is coupled to an arm 120. The shaft 118 is configured to be rotatable by a drive mechanism such as a motor 122 and a drive belt. Accordingly, the head 106 that holds the photocatalyst 104 is rotatable. The shaft 118 is configured to be movable in an up-down direction by an elevating mechanism such as a ball screw 124. Therefore, a gap between the photocatalyst 104 held onto the head 106 and the substrate WF held onto the table 102 can be adjusted by the elevating mechanism. While the photocatalyst 104 and the substrate WF are basically contactless, adjusting the gap between the substrate WF and the photocatalyst 104 allows changing a reaching distance of a reactive species generated by the photocatalyst 104 to the substrate WF, thereby allowing an adjustment of selectivity of a process speed to an unevenness of a material of the substrate WF surface. The arm 120 is coupled to a rotatable shalt 126. The shaft 126 is configured to be rotatable by a drive mechanism such as a motor 128 and a drive belt. Accordingly, the head 106, which holds the photocatalyst 104, allow pivotal movement about the shaft 126 in a direction parallel to a plane of the substrate WF on the table 102. The conditioner 150 is disposed in a range of a swing movement of the arm 120. Accordingly, the head 106 that holds the photocatalyst 104 can move between the table 102 and the conditioner 150.

In one embodiment, as illustrated in FIG. 1C, the head 106 includes a head body 130. The head body 130 is coupled to the shaft 118, and mostly defines an outer shape of the head 106. A base 132 is mounted to the head body 130. The base 132 is formed of a flat plate-shaped member. The base 132 is preferably formed of a material transparent to an excitation light for exciting the photocatalyst 104 described later. The base 132 preferably has an optical transmittance of 80% or more in a wavelength of the excitation light. The base 132 can be formed of, for example, any organic optical material including quartz, crystal, sapphire, acrylic resin, and polycarbonate. A transparent conductive layer may be formed on the surface of the base 132. The transparent conductive layer can be ITO, FTO, Ga₂O₃, ZnO-based, SnO₂-based, or the like.

The photocatalyst 104 is formed on the lower surface of the base 132. The photocatalyst 104 can be TiO₂, WO₃, SrTiO₃, or the like. The photocatalyst 104 can be formed on the surface of the base 132 by a resistance heating type vapor deposition method, a chemical vapor deposition method (CVD), a sputtering method, a plating method, and the like. The photocatalyst 104 internally generates electrons and electron holes when receiving a light from a light source 134 described below, and generates a reactive species for etching a target to be processed of the substrate WF by a reaction of the generated electron and electron holes and a process liquid. While not illustrated, a conductive body may be disposed between the photocatalyst 104 and the base 132. The conductive body is preferably arranged not to decrease the amount of the light that reaches the photocatalyst 104 from the light source 134. For example, the conductive body may be arranged like a checkered pattern, or may be arranged in a grid-like pattern. The conductive body may be connected to an opposite electrode disposed in a range of contacting the process liquid described below. Furthermore, an external power source may be connected between the conductive body and the opposite electrode, thereby allowing voltage application between the conductive body and the opposite electrode. By disposing the conductive body and the opposite electrode, the distribution of the electrons and the electron holes generated by the photocatalyst 104 in the photocatalyst 104 can be controlled, and furthermore, the voltage application by the external power source acts to accelerate the control of the distribution.

As illustrated in FIG. 1C, the substrate processing apparatus 10 includes the light source 134. The substrate processing apparatus 10 includes a light introduction path 136 that introduces the light from the light source 134 into the head 106. The light introduction path 136 can be an optical fiber or the like. In one embodiment, as illustrated in FIG. 1C, the light introduction path 136 is configured to introduce the light inside the head 106 passing through the shaft 126, the arm 120, and the shaft 118, The light source 134 can be a light source that generates a light having a wavelength that can excite the photocatalyst 104. More specifically, the light source 134 is a light source that generates a light having a wavelength with an energy of a bandgap or more of the photocatalyst 104. In one embodiment, the light source 134 is a light source that generates a light having a wavelength of an ultraviolet (UV) range. For example, when the photocatalyst 104 is TiO₂, the light source 134 is a light source that generates a light having a wavelength of 380 nm or less, and can be a light source that generates a light having a wavelength of, fix example, 365 nm. As one embodiment, the light source 134 may be disposed inside the head 106.

As illustrated in FIG. 1C, the head 106 includes an optical system 138. The optical system 138 is configured to uniformly irradiate the whole surface of the photocatalyst 104 with the light introduced inside the head 106 from the light introduction path 136 or a light from the light source 134 disposed inside the head 106 via the base 132. The optical system 138 can include any optical element and a combination of optical elements. For example, the optical system 138 can be a convex lens that uniformly parallelizes the light toward the photocatalyst 104. Alternatively, in one embodiment, the optical system 138 may be a concave mirror that uniformly parallelizes the light toward the photocatalyst 104 while not illustrated. Alternatively, in one embodiment, the optical system 138 can be a concave lens that uniformly diffuses the light toward the photocatalyst 104.

In one embodiment, the substrate processing apparatus 10 includes the nozzle 108 for supplying a process liquid on the top of the substrate WF arranged on the table 102. The nozzle 108 is coupled to a process liquid supply source 140 via a flow passage 142. In one embodiment, as illustrated in FIG. 1A, the nozzle 108 includes two nozzles 108a, 108b. As illustrated in FIG. 1A, the flow passage 142 branches, and one flow passage 142a is connected to the nozzle 108a disposed in the proximity of an outer periphery of the table 102. The nozzle 108a may be disposed above the table 102. The nozzle 108a may be configured to be movable. For example, by moving the nozzle 108a. in synchronization with the head 106, the process liquid can be efficiently supplied to a processing surface between the substrate WF and the photocatalyst 104, The other branched flow passage 142b may be communicated with the inside of the head 106 passing through the shaft 126, the arm 120, and the shaft 118, and connected to the nozzle 108b disposed inside the head 106, In one embodiment, the nozzle 108b inside the head 106 can be an opening portion provided to the head body 130 and the base 132. As illustrated in FIG. 1A, a valve 144a is disposed on the flow passage 142a, and is configured to supply the process liquid from the nozzle 108a to the top of the substrate WF at any timing. As illustrated in FIG. 1A, a valve 144b is disposed on the flow passage 142b, and is configured to supply the process liquid from the nozzle 108b to the top of the substrate WF at any timing. In one embodiment, the substrate processing apparatus 10 may include only one of the above-described nozzles 108a, 108b. The process liquid can be selected depending on the material of the surface of the substrate as the process target and the photocatalyst to be used. The process liquid can contain pure water, an oxidant, a pH regulator, a chelating agent, and the like, and the process liquid corresponding to the process target can be made by adjusting their combination. The oxidant can be H₂O₂, ammonium persulfate (APS), or the like, the pH regulator can be inorganic acid/base such as HCl, KG, KOH, or NH₃, the chelating agent can be organic acid/base such as citric acid, ethylenediamine tetraacetic acid (EDTA), or the like. The etching of the substrate surface material by the process liquid itself (hereinafter, free etching) is preferably small as much as possible from the aspect of the process speed control. For the purpose of suppressing the free etching, an additive, such as an anticorrosive of BTA or the like, may be further added to the process liquid. As this additive, one that acts to the substrate surface material of the substrate WF is suitable, and one that acts a little or does not act to the photocatalyst 104 is preferred.

In one embodiment the substrate processing apparatus 10 can include a temperature controller 141 that controls the temperature of the process liquid. The temperature controller 141 can be disposed, for example, midway on the flow passage 142 of the process liquid. The temperature controller 141 can be any temperature controller that controls a liquid temperature by, for example, a direct heating by an infrared heater or a heating wire, or an indirect control using a heat exchanger or the like. The temperature of the process liquid supplied from the nozzle 108 can he controlled by the temperature controller 141.

In one embodiment, the substrate processing apparatus 10 includes the conditioner 150 for performing the conditioning of the photocatalyst 104. In this conditioning, an etching product attached to the surface of the photocatalyst 104 is removed, and an alteration in property of the photocatalyst 104 itself is recovered, thereby recovering the catalytic ability of the photocatalyst 104. FIG. 1D is a side view schematically illustrating a state of performing the conditioning to the photocatalyst 104. FIG. 1D partially illustrates a cross-sectional surface. The conditioner 150 according to one embodiment includes a conditioning tank 152, The conditioning tank 152 can hold the conditioning liquid, and has dimensions enough to accept the photocatalyst 104 held onto the head 106.

In one embodiment, the conditioning tank 152 can include a temperature controller 153 that controls a temperature of a conditioning liquid. In one embodiment, the temperature controller 153 can include a heating element, such as a heating wire, and a cooling element, such as a Peltier element, which are disposed in the conditioning tank 152. In one embodiment, the temperature controller 153 can be configured to flow a fluid (for example, water) at a controlled temperature to a fluid passage formed in the conditioning tank 152. The temperature of the conditioning liquid held in the conditioning tank 152 can be controlled by the temperature controller 153.

In the illustrated embodiment, the photocatalyst 104 is irradiated with the light from the light source 134 in a state where the photocatalyst 104 is immersed in the conditioning liquid held in the conditioning tank 152, thereby allowing the conditioning of the photocatalyst 104. The etching process of the substrate WF using the photocatalyst 104 possibly reduces the catalytic activity due to the attachment of the removed material and the like from the substrate WF to the photocatalyst 104. Therefore, by performing the conditioning to the photocatalyst 104, the activity power of the photocatalyst 104 can be maintain or restored. The conditioning liquid used for the conditioning may be the same as the process liquid used for processing the substrate WF arranged on the table 102, or may be a different liquid. Here, the different liquid may be one in which a part of the components of the process liquid is removed (for example, the oxidant is removed). The light source used for the conditioning only needs to have a wavelength that can excite the photocatalyst 104, and may be the same as the light source 134 used for processing the substrate WF arranged on the table 102 or may be a different light source. While the light irradiation is not necessary when the conditioning liquid itself contains a conditioning component that recovers the photocatalyst 104, when the conditioning component is generated by the light irradiation, appropriately adjusting the irradiation intensity of the light from the light source 134 allows the adjustment of the conditioning speed. While not illustrated, in the case of the configuration in which the conductive body is disposed between the photocatalyst 104 and the base 132, and the voltage can be applied by the external power source, the voltage may be applied by the external power source during the conditioning.

In one embodiment, the substrate processing apparatus 10 includes a catalyst sensor 154 that measures the activity power of the photocatalyst 104. In one embodiment, the catalyst sensor 154 can be any electrical resistance measuring instrument. The electrical resistance measuring instrument can be one that measures between any two points of the photocatalyst 104. It is used that the electrical resistance of the photocatalyst 104 changes because the photocatalyst reaction is hindered due to the attachment of the removed material and the like from the substrate WF to the photocatalyst 104 when the substrate WF is processed by the photocatalyst 104. For example, the attachment of the removed material with high resistance increases the electrical resistance of the photocatalyst 104 during the excitation light irradiation. In this case, by performing the conditioning, the attached material and the like are removed from the photocatalyst 104, and the electrical resistance of the photocatalyst 104 decrease during the excitation light irradiation. When the removed material with low resistance attaches the photocatalyst 104, the electrical resistance of the photocatalyst 104 in the state of not being irradiated with the excitation light decreases. In this case, by performing the conditioning, the electrical resistance of the photocatalyst 104 in the state of not being irradiated with the excitation light increases. Accordingly, by measuring the electrical resistance of the photocatalyst 104 in the state of being irradiated with the excitation light and the state of not being irradiated with the excitation light, the activity power of the photocatalyst 104 can be determined. Probes 156 of the electrical resistance measuring instrument as the catalyst sensor 154 may be disposed inside the conditioning tank 152, For example, by disposing the head 106 such that the photocatalyst 104 is immersed in the conditioning liquid in the conditioning tank 152, the probes 156 of the electrical resistance measuring instrument can be disposed such that the probes 156 contact the photocatalyst 104.

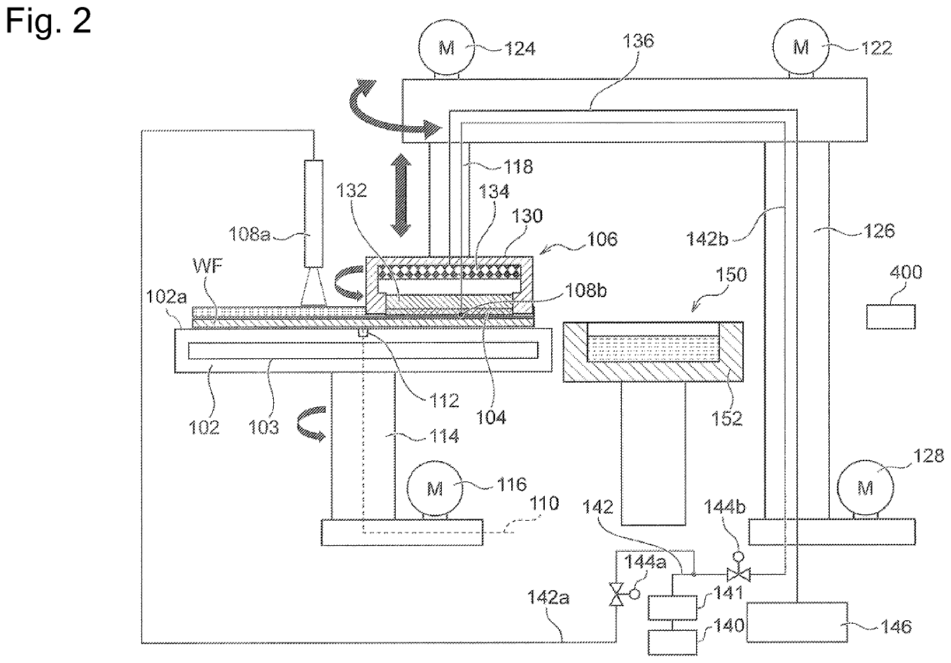

FIG. 2 is a side view schematically illustrating a substrate processing apparatus according to one embodiment. Note that FIG. 2 partially illustrates a cross-sectional surface. A substrate processing apparatus 10 according to the embodiment illustrated in FIG. 2 includes a light source 134 inside a head 106. The light source 134 disposed inside the head 106 can be any given one. In one embodiment, the light source 134 inside the head 106 can include a plurality of light emitting elements. For example, by mounting a plurality of minute UV-LED light sources, the light source can be configured to include a plurality of optical elements that are two-dimensionally disposed. The plurality of two-dimensionally disposed optical elements are configured to uniformly irradiate the photocatalyst 104 via the base 132. In one embodiment, the head 106 of the substrate processing apparatus 10 according to the embodiment illustrated in FIG. 2 may include an optical system for uniformly irradiating the photocatalyst 104 with the light from the light source 134 via the base 132. In one embodiment, the substrate processing apparatus 10 includes a power source 146, and is configured to supply an electric power to the light source 134 inside the head 106 via the shaft 126, the arm 120, and the shaft 118 as illustrated in FIG. 2. The substrate processing apparatus 10 according to the embodiment illustrated in FIG. 2 can have any configuration except that the light source 134 is disposed inside the head 106, and can have the configuration similar to that of the embodiment indicated with FIG. 1. When a plurality of light sources are mounted, an irradiation region may be divided into a plurality of regions for each light source and the irradiation intensities from the respective light sources may be adjusted, thereby adjusting an intensity distribution of the light irradiation to the photocatalyst 104. By adjusting the light irradiation intensity distribution, an amount of generating reactive species by a photocatalyst reaction in the head 106 plane can be distributed, thus providing a factor to control an in-plane uniformity of the substrate of the process speed when, for example, the head 106 is swung on the whole surface of the substrate WF.

While one head 106 is mounted to one arm 120 in the substrate processing apparatuses 10 according to the embodiments illustrated in FIGS. 1 and 2, as another embodiment, the substrate processing apparatus 10 may include a plurality of arms 120, and one head 106 may he disposed for each arm 120. In one embodiment, a plurality of heads 106 may be mounted to one arm 120. In one embodiment, one or more of any number of heads 106 may be mounted to each of a plurality of arms 120.

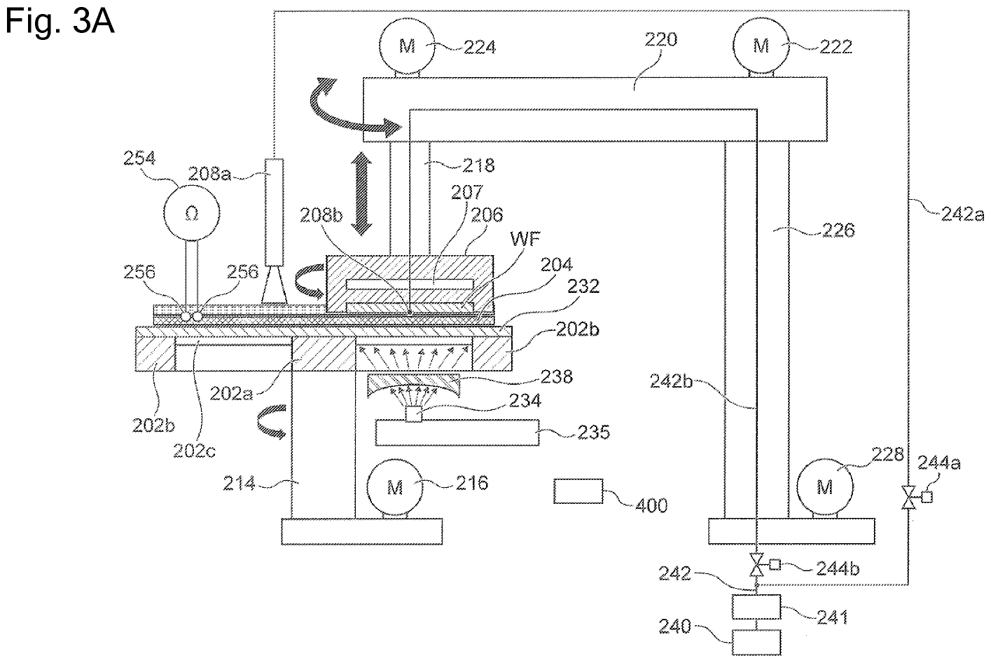

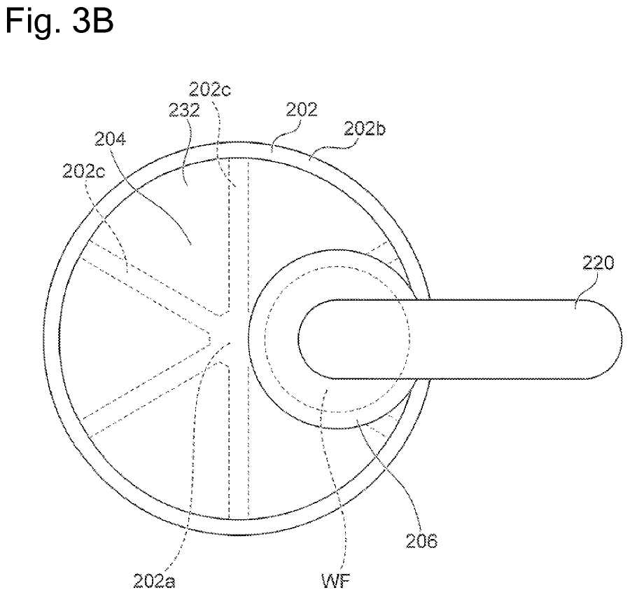

FIG. 3A is a side view schematically illustrating a substrate processing apparatus according to one embodiment. Note that FIG. 3A partially illustrates a cross-sectional surface. FIG. 3B is a top view schematically illustrating the substrate processing apparatus illustrated in FIG. 3A. The substrate processing apparatus illustrated in FIGS. 3A, 3B can be configured as a part of a substrate processing system or one unit in the substrate processing system that includes a CMP apparatus, which performs a polishing process of a substrate such as a semiconductor wafer, a cleaning device, and the like.

As illustrated in FIG. 3A, a substrate processing apparatus 10 according to one embodiment includes a table 202 for holding a photocatalyst 204, a head 206 fix holding a substrate, a nozzle 208 for supplying a process liquid, and a controller 400.

As illustrated in FIG. 3A, the head 206 is connected to a rotatable shaft 218. The shaft 218 is coupled to an arm 220. The shaft 218 is configured to be rotatable by a drive mechanism such as a motor 222 and a drive belt. Accordingly, the head 206 that holds the substrate WF is rotatable. The shaft 218 is configured to be movable in an up-down direction by an elevating mechanism such as a ball screw 224. Therefore, a gap between the substrate WF held onto the head 206 and the photocatalyst 204 held onto the table 202 can be adjusted by the elevating mechanism. The arm 220 is coupled to a rotatable shaft 226. The shaft 226 is configured to be rotatable by a drive mechanism such as a motor 228 and a drive belt. Accordingly, the head 206, which holds the substrate WF, allow pivotal movement about the shaft 226 in a direction parallel to a plane of the photocatalyst 204 on the table 202.

In one embodiment, the head 206 can include a temperature controller 207. in one embodiment, the temperature controller 207 can include a heating element, such as a heating wire, and a cooling element, such as a Peltier element, which are disposed in the head 206. In one embodiment, the temperature controller 207 can be configured to flow a fluid (for example, water and a process liquid) at a controlled temperature to a fluid passage formed in the head 206. The temperature of the substrate WF held onto the head 206 can be controlled by the temperature controller 207.

As illustrated in FIGS. 3A, 3B, the table 202 includes a center portion 202a, an outer race portion 202b, and a plurality of coupling portions 202c radially extending from the center portion 202a to the outer race portion 202b. As illustrated in FIG. 3A, the center portion 202a of the table 202 is coupled to a drive shaft 214. The drive shaft 214 is configured to be rotatable by a drive mechanism such as a motor 216 and a drive belt. Therefore, the table 202 is configured to be rotatable. In one embodiment, as illustrated in FIG. 3A, a base 232 is mounted to the top of the table 202. The base 232 is formed of a flat plate-shaped member. The base 232 is preferably formed of a material transparent to an excitation light for exciting the photocatalyst 204. The base 232 preferably has an optical transmittance of 80% or more. The base 232 can be formed of, for example, any organic optical material including quartz, crystal, sapphire, acrylic resin, and polycarbonate. A transparent conductive layer may be formed on the surface of the base 232. The transparent conductive layer can be ITO, FTO, Ga₂O₃, ZnO-based, SnO₂-based, or the like.

In the illustrated embodiment, the photocatalyst 204 is held onto the top surface of the base 232. The photocatalyst 204 can be TiO₂, WO₃, ZnO₂, SrTiO₃, or the like. The photocatalyst 204 can be formed on the surface of the base 232 by a resistance heating type vapor deposition method, a chemical vapor deposition method (CVD), a sputtering method, a plating method, and the like. While not illustrated, a conductive body may be disposed between the photocatalyst 204 and the base 232. The conductive body is preferably arranged not to decrease the amount of the light that reaches the photocatalyst 204 from a light source 234. For example, the conductive body may be arranged like a checkered pattern, or may be arranged in a grid-like pattern. The conductive body may be connected to an opposite electrode disposed in a range of contacting the process liquid described below. Furthermore, an external power source may be connected between the conductive body and the opposite electrode, thereby allowing voltage application between the conductive body and the opposite electrode. By disposing the conductive body and the opposite electrode, the distribution of the electrons and the electron holes generated by the photocatalyst 204 in the photocatalyst 204 can be controlled, and furthermore, the voltage application by the external power source acts to accelerate the control of the distribution.

As illustrated in FIG. 3A, the substrate processing apparatus 10 includes the light source 234. The light source 234 can be a light source that generates a light having a wavelength that can excite the photocatalyst 204. More specifically, the light source 234 is a light source that generates a light having a wavelength with an energy of a handgap or more of the photocatalyst 204. In one embodiment, the light source 234 is a light source that generates a light having a wavelength of an ultraviolet (UV) range. For example, when the photocatalyst 204 is TiO₂, the light source 234 is a light source that generates a light having a wavelength of 380 nm or less, and can be a light source that generates a light having a wavelength of, for example, 365 nm.

As illustrated in FIG. 3A, the light source 234 is disposed below the table 202. In one embodiment, as illustrated in FIG. 3A, the substrate processing apparatus 10 includes an optical system 238. The optical system 238 is configured to uniformly irradiate at least a part of the photocatalyst 204 with a light from the light source 234 via the base 232. In the embodiment illustrated in FIG. 3A, the light source 234 and the optical system 238 are configured such that the light from the light source 234 uniformly irradiates the photocatalyst 204 in a contact region of the substrate WF and the photocatalyst 204. In one embodiment, the light source 234 and the optical system 238 can be configured to be movable in a direction parallel to a plane of the photocatalyst 204. For example, the light source 234 and the optical system 238 can be controlled to be moved with respect to the substrate WF so as to uniformly etch the substrate WF. For example, the light source 234 and the optical system 238 can be configured to be movable by mounting the light source 234 and the optical system 238 to a movable support table 235. The optical system 238 can include any optical element including a convex lens, a concave lens, a mirror, and the like, and a combination of any optical elements.

In one embodiment, the substrate processing apparatus 10 includes a nozzle 208 for supplying a process liquid to the top of the photocatalyst 204 held onto the table 202. The nozzle 208 is coupled to a process liquid supply source 240. In one embodiment, as illustrated in FIG. 3A, the nozzle 208 includes two nozzles 208a, 208b. As illustrated in FIG. 3A, one nozzle 208a is connected to the process liquid supply source 240 by a flow passage 242a and disposed in the proximity of the outer periphery of the table 202, or the nozzle 208a may be disposed above the table 202. The nozzle 208a may be configured to be movable. For example, by moving the nozzle 208a in synchronization with the head 206, the process liquid can be efficiently supplied to a processing surface between the substrate WF and the photocatalyst 204. The other nozzle 208b may be connected to the process liquid supply source 240 and be disposed inside the head 206 via a flow passage 242b passing through the shaft 226, the arm 220, the shaft 218, and inside the head 206. As illustrated in FIG. 3A, a valve 244a is disposed on the flow passage 242a, and is configured to supply the process liquid from the nozzle 208a to the top of the photocatalyst 204 at any timing. As illustrated in FIG. 3A, a valve 244b is disposed on the flow passage 242b, and is configured to supply the process liquid from the nozzle 208b to the top of the photocatalyst 204 at any timing. In one embodiment, the substrate processing apparatus 10 may include only one of the above-described nozzles 208a, 208b.

In one embodiment, the substrate processing apparatus 10 can include a temperature controller 241 that controls the temperature of the process liquid. The temperature controller 241 can be disposed, for example, midway on the flow passage 242 of the process liquid. The temperature controller 241 can be any temperature controller that controls a. liquid temperature by, for example, a direct heating by an infrared heater or a heating wire, or an indirect control using a heat exchanger or the like. The temperature of the process liquid supplied from the nozzle 208 can be controlled by the temperature controller 241.

In one embodiment, the substrate processing apparatus 10 includes a catalyst sensor 254 that measures the activity power of the photocatalyst 204. In one embodiment, the catalyst sensor 254 can be any electrical resistance measuring instrument. The electrical resistance measuring instrument can be one that measures between any two points of the photocatalyst 204. The electrical resistance measuring instrument as the catalyst sensor 254 includes a probe 256 disposed to be contactable to the photocatalyst 204 on the table 202. The conditioning of the photocatalyst 204 on the table 202 can be performed by irradiating the photocatalyst 204 with the excitation light from the light source 234 while supplying the conditioning liquid to the top of the photocatalyst 204 in a state of not bringing the substrate WF into contact with the photocatalyst 204. The conditioning liquid may be supplied using the above-described nozzles 208a and/or 208b by switching the supply liquid from the process liquid. In the conditioning, the activity power of the photocatalyst 204 may be measured by the catalyst sensor 254. The conditioning liquid may be the same as the process liquid used for processing the substrate WF, or may be a different liquid. While the light irradiation is not necessary when the conditioning liquid itself contains a conditioning component that recovers the photocatalyst 204, when the conditioning component is generated by the light irradiation, appropriately adjusting the irradiation intensity of the light from the light source 234 allows the adjustment of the conditioning speed. For efficiently performing the conditioning, a plurality of light sources for performing the conditioning may be disposed. While not illustrated, in the case of the configuration in which the conductive body is disposed between the photocatalyst 204 and the base 232, and the voltage can be applied by the external power source, the voltage may be applied by the external power source during the conditioning.

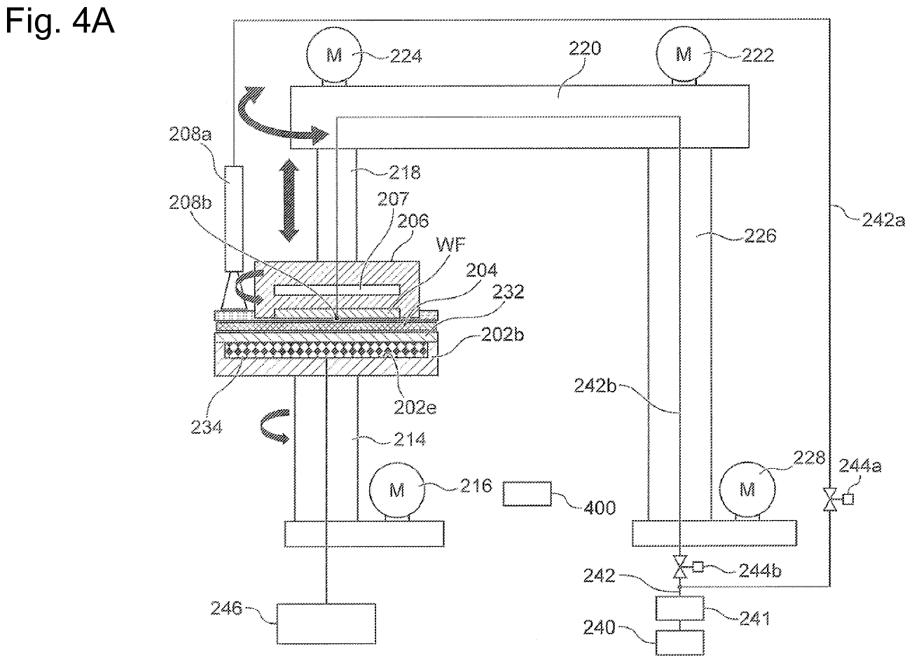

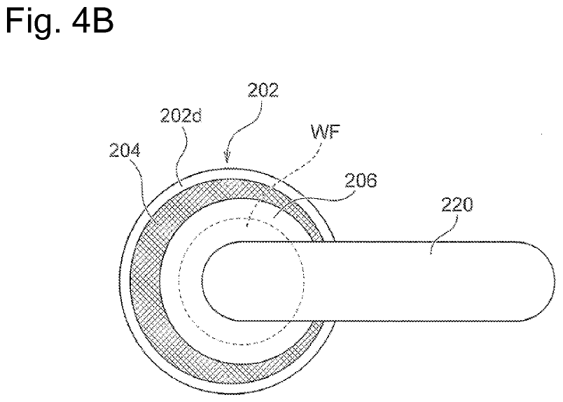

FIG. 4A is a side view schematically illustrating a substrate processing apparatus according to one embodiment. Note that FIG. 4A partially illustrates a cross-sectional surface. FIG. 4B is a top view schematically illustrating the substrate processing apparatus illustrated in FIG. 4A. The substrate processing apparatus illustrated in FIGS. 4A, 4B can be configured as a part of a substrate processing system or one unit in the substrate processing system that includes a CMP apparatus, which performs a polishing process of a substrate such as a semiconductor wafer, a cleaning device, and the like.

As illustrated in FIG. 4A, a substrate processing apparatus 10 according to one embodiment includes a table 202 for holding a photocatalyst 204, a head 206 for holding a substrate, and a nozzle 208 for supplying a process liquid.

As illustrated in FIG. 4A, the head 206 is connected to a rotatable shaft 218. The shaft 218 is coupled to an arm 220. The shaft 218 is configured to be rotatable by a drive mechanism such as a motor 222 and a drive belt. Accordingly, the head 206 that holds the substrate WF is rotatable. The shaft 218 is configured to be movable in an up-down direction by an elevating mechanism such as a ball screw 224. Therefore, a gap between the substrate WF held onto the head 206 and the photocatalyst 204 held onto the table 202 can be adjusted by the elevating mechanism. The arm 220 is coupled to a rotatable shaft 226. The shaft 226 is configured to be rotatable by a drive mechanism such as a motor 228 and a drive belt. Accordingly, the head 206, which holds the substrate WF, allow pivotal movement about the shaft 226 in a direction parallel to a plane of the photocatalyst 204 on the table 202.

As illustrated in FIGS. 4A, 4B, the table 202 has a shape of tray in which an edge portion 202d of the outer periphery is formed to be high. Alternatively, it can be said that the table 202 is provided with a depressed portion 202e excluding the edge portion 202d of the outer periphery. As illustrated in FIG. 4A, the table 202 is coupled to a drive shaft 214. The drive shaft 214 is configured to be rotatable by a drive mechanism such as a motor 216 and a drive belt. Therefore, the table 202 is configured to be rotatable. In one embodiment, as illustrated in FIG. 4A, a base 232 is mounted to the edge portion 202d of the outer periphery of the table 202. The base 232 is formed of a flat plate-shaped member. The base 232 is preferably formed of a material transparent to an excitation light for exciting the photocatalyst 204. The base 232 preferably has an optical transmittance of 80% or more. The base 232 can be formed of, for example, any organic optical material including quartz, crystal, sapphire, acrylic resin, and polycarbonate. A transparent conductive layer may be formed on the surface of the base 232. The transparent conductive layer can be ITO, FTO, Ga₂O₃, ZnO-based, SnO₂-based, or the like.

In the illustrated embodiment, the photocatalyst 204 is held onto the top surface of the base 232. The photocatalyst 204 can be TiO₂, WO₃, ZnO₂, SrTiO₃, or the like. The photocatalyst 204 can be formed on the surface of the base 232 by a resistance heating type vapor deposition method, a chemical vapor deposition method (CND), a sputtering method, a plating method, and the like.

As illustrated in FIG. 4A, the substrate processing apparatus 10 includes the light source 234. The light source 234 can be a light source that generates a light having a wavelength that can excite the photocatalyst 204. More specifically, the light source 234 is a light source that generates a light having a wavelength with an energy of a bandgap or more of the photocatalyst 204. In one embodiment, the light source 234 is a light source that generates a light having a wavelength of an ultraviolet (UV) range. For example, when the photocatalyst 204 is TiO₂, the light source 234 is a light source that generates a light having a wavelength of 380 nm or less, and can be a light source that generates a light having a wavelength of, for example, 365 nm.

As illustrated in FIG. 4A, the light source 234 is disposed inside the depressed portion 202e of the table 202. In one embodiment, the light source 234 in the table 202 can include a plurality of light emitting elements. For example, it can be a light source in which a plurality of optical elements are two-dimensionally disposed. The two-dimensionally disposed plurality of optical elements are configured to uniformly irradiate at least a part of the region of the photocatalyst 204 via the base 232. Specifically, the plurality of optical elements are configured such that the light from the light source 234 uniformly irradiates the photocatalyst 204 in a contact region of the substrate WF and the photocatalyst 204. In one embodiment, any optical system for uniformly irradiating the photocatalyst 204 with the light from the light source 234 may be disposed in the depressed portion 202e of the table 202. In one embodiment, the substrate processing apparatus 10 includes a power source 246, and is configured to supply an electric power to the light source 234 inside the table 202 via the drive shaft 214 as illustrated in FIG. 4A. The substrate processing apparatus 10 according to the embodiment illustrated in FIGS. 4A, 4B can have a configuration similar to that in the embodiment described with FIG. 3 except the structure of the table 202 and that the light source 234 and the like are disposed inside the table 202. When a plurality of light sources are mounted, an irradiation region may be divided into a plurality of regions for each light source and the irradiation intensities from the respective light sources may be adjusted, thereby adjusting an intensity distribution of the light irradiation to the photocatalyst 204.

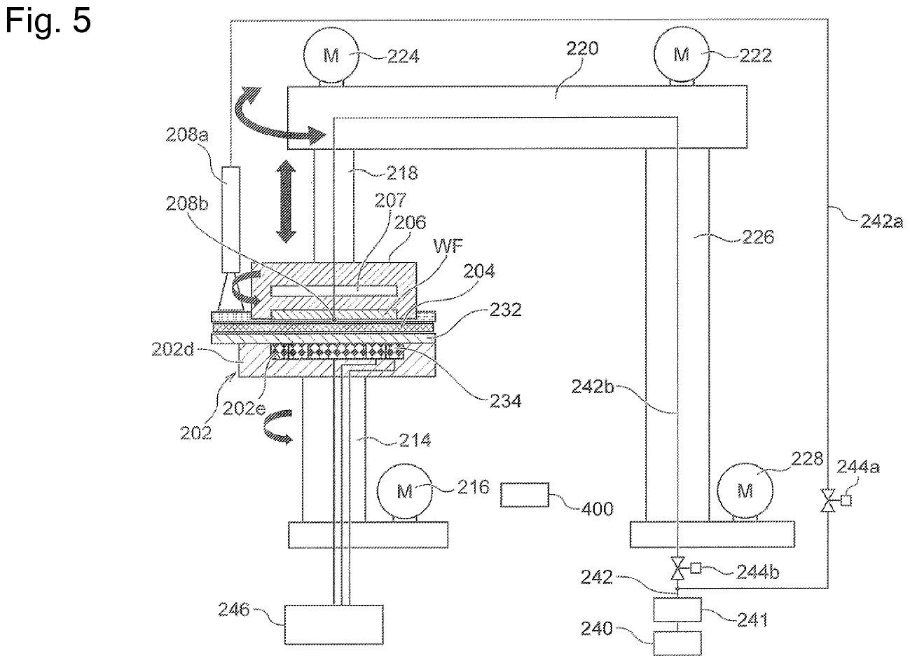

FIG. 5 is a side view schematically illustrating a substrate processing apparatus according to one embodiment. Note that FIG. 5 partially illustrates a cross-sectional surface. A substrate processing apparatus 10 according to the embodiment illustrated in FIG. 5 has a configuration mostly similar to that of the substrate processing apparatus 10 according to the embodiment illustrated in FIG. 4. In the embodiment illustrated in FIG. 5, the light source 234 disposed in the table 202 is configured to include a plurality of regions and to control the light intensity for each region. In one embodiment, the light source 234 is configured to concentrically include a plurality of regions and to control the light intensity for each region, By adjusting the light irradiation intensity distribution, an amount of generating reactive species by a photocatalyst reaction can be distributed, thus providing a factor to control an in-plane uniformity of the substrate WF of the process speed.

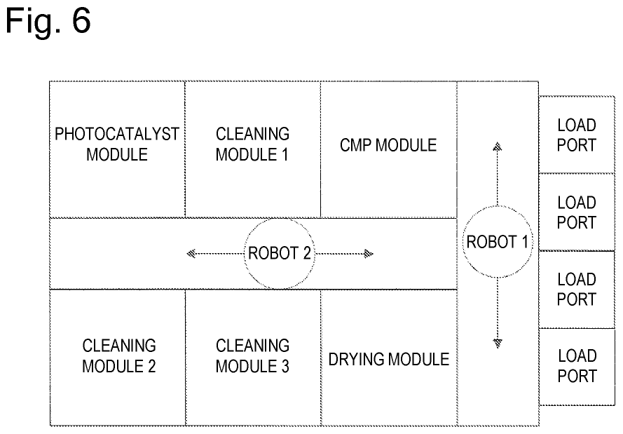

FIG. 6 is a block diagram schematically illustrating a substrate processing system according to one embodiment. The substrate processing system includes load ports, a CMP module, a photocatalyst module, cleaning modules, and a drying module, The substrate processing system includes robots that transfer a substrate in the substrate processing system. In the substrate processing system illustrated in FIG. 6, the load ports hold the substrate before the processing and hold the substrate after the processing. A robot 1 can receive the substrate before the processing from the load port and can hand over the substrate to a robot 2. The robot 2 can transfer the substrate among the CMP module, the photocatalyst module, cleaning modules 1, 2, and 3, the drying module, and the robot 1. The photocatalyst module in the substrate processing system can have any feature of the above-described substrate processing apparatus 10. The configuration of the substrate processing system excluding the photocatalyst module can be any configuration, and the type and the number of the modules is appropriately set. In this configuration, for example, the substrate WF processed by the CMP module can be subjected to a finishing process by the photocatalyst module.

The following describes a substrate processing method using a photocatalyst. The substrate processing method can be executed by any substrate processing apparatus 10 described above. The operation of the substrate processing apparatus 10 can be controlled by the controller 400. In the substrate processing method using the photocatalyst according to this disclosure, the substrate and the photocatalyst are brought close to one another in the presence of the process liquid, and the photocatalyst is irradiated with the excitation light, thereby performing an etching process on the surface of the substrate.

As one example, the principle of substrate processing using TiO₂ as a photocatalyst will be described. When TiO₂ is irradiated with a light (UV light) having the energy of band gap or more and the wavelength of 380 nm or less, electron-hole pairs are generated. The electrons excited from a valence band to a conductor react with oxygen, and the electron holes generated in the valence band react with water, thus generating hydroxyl radical (OH.) as an active species. Since the hydroxyl radical as an active species has a considerably high oxidation power, oxidation removal of the substrate surface can be performed using the hydroxyl radical. Since the lifespan of the hydroxyl radical is short, a diffusion distance of the generated hydroxyl radical is limited to the proximity of the TiO₂ surface. Accordingly, the removal proceeds preferentially from the projecting portion of the substrate surface close to the TiO₂ surface.

2TiO₂+hv→TiO₂[h+]+TiO₂[e−]

TiO₂[e−]+O₂→TiO₂+O₂.−

TiO₂[h+]+H₂O→TiO₂+OH.+H+

Here, when a chemical substance that reacts with the electron holes or the electrons is insufficient, the electrons and the electron holes recombine to generate a thermal energy, thus generating nothing as a chemical reaction. Accordingly, a device to avoid the recombination of the generated electrons and electron holes is required. H₂O is sufficiently present in the process liquid, and the reaction of electron holes is considered to easily proceed. For O₂ that reacts with the electrons, since dissolved oxygen in the process liquid alone is considered to be insufficient, it is preferred to use H₂O₂ or the like that generates oxygen by a self-decomposition reaction for the process liquid. Since it is also considered that the generated electrons react with an oxidant, it is preferred that the process liquid contains an oxidant.

As control factors of the hydroxyl radical generation amount in the photocatalyst reaction, (1) photocatalytic activity, (2) excitation light irradiation intensity, (3) type and concentration of process liquid, (4) process liquid supply amount, and the like are considered. (2) Excitation light irradiation intensity affects the generation amount of the electron-hole pair. (3) Type and concentration of process liquid and (4) process liquid supply amount affect the amount of the chemical substance (for example, oxygen) that reacts with the electrons.

The activity power of TiO₂ is mainly determined by the crystallinity and the thickness of TiO₂. The catalytic activity can be obtained by measuring the electrical resistance of the photocatalyst during the irradiation of the excitation light. When the removed material of the substrate or the like attaches the TiO₂ surface and the catalytic activity is decreased, TiO₂ is immersed in an appropriate process liquid in which a photocatalyst reaction occurs and is irradiated with the excitation light in the process liquid, thereby allowing the decomposition and removal of foreign objects attached to the TiO₂ surface by hydroxyl radical generated on the TiO₂ surface (conditioning).

When the photocatalyst is irradiated with the excitation light, the recombination rate of the electrons and the electron holes increases when oxygen or the oxidant to react with the electrons is not sufficiently present. When the electrons and the electron holes are recombined, while a thermal energy and a light energy are generated, nothing is generated as a chemical reaction, and the removal of the substrate does not proceed. Accordingly, for efficiently performing the removal of the substrate, it is necessary to avoid the recombination of the electrons and the electron holes generated in the irradiation of the photocatalyst with the excitation light, and therefore, it is necessary to supply the process liquid to the photocatalyst by a sufficient amount. To sufficiently supply the process liquid between the substrate and the photocatalyst, it is effective to provide an appropriate gap between the photocatalyst and the substrate surface, and to cause the photocatalyst and the substrate to relatively move.

As control factors of the removal amount of the substrate surface in the substrate processing using the photocatalyst, (1) hydroxyl radical amount, (2) distance between photocatalyst and substrate surface, and (3) temperature are considered. By controlling the generation amount of hydroxyl radical, the removal amount of the substrate surface can be controlled. When the distance between the photocatalyst and the substrate surface is increased, the hydroxyl radical generated on the surface of the photocatalyst is inactivated before reaching the substrate surface, and therefore, the removal of the substrate surface is not performed. Meanwhile, when the distance between the surface of the photocatalyst and the substrate surface is decreased, the process liquid is not sufficiently supplied to the surface of the photocatalyst, and therefore, the photocatalyst reaction does not proceed. In consideration of this, it is preferred to appropriately control the distance between the surface of the photocatalyst and the substrate surface. Furthermore, since it is considered that the reaction in which the hydroxyl radical is generated and the diffusion distance of the hydroxyl radical depend on the temperature, the temperature control is also effective for controlling the removal amount of the substrate surface.

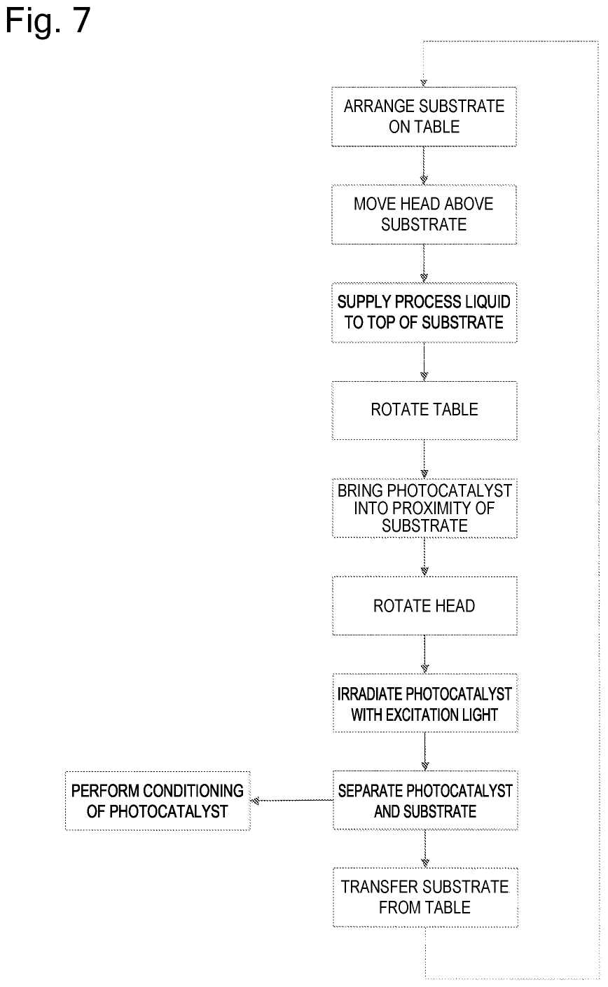

As one example, a substrate processing method using the substrate processing apparatus 10 described with FIGS. 1, 2 will be described. FIG. 7 is a flowchart illustrating a substrate processing method according to one embodiment. The substrate WF is held onto the table 102. The installation of the substrate WF to the table 102 may be performed using any robot, or may be manually performed. When the table 102 includes the temperature controller 103, the temperature of the substrate WF on the table 102 may be controlled to become a predetermined temperature by the temperature controller 103.

Next, the arm 120 is driven, thus mowing the head 106 such that the head 106 is arranged above the substrate WF on the table 102.

Next, the process liquid is supplied to the substrate WF on the table 102. The supply of the process liquid may be performed from the nozzle 108b disposed to the head 106, may be performed from the nozzle 108a outside the head 106, and may be performed from both nozzles 108a, 108b. At this time, the table 102 is rotated. When the substrate processing apparatus 10 includes the temperature controller 141, the supplied process liquid may be controlled to have a predetermined temperature by the temperature controller 141.

Next, the head 106 is moved toward the table 102 so as to bring the photocatalyst 104 in the proximity. The distance between the surface of the substrate WF and the surface of the photocatalyst 104 is determined from a recipe of the processing performed to the substrate, the lifespan of the active species generated by the photocatalyst reaction, the amount of the process liquid present between the photocatalyst and the substrate, and the like. For example, it is preferred to adjust the distance between the photocatalyst 104 and the substrate WF such that the distance between the surface of the substrate WF and the surface of the photocatalyst 104 becomes about 1 μm or more and about 500 μm or less, and more preferably, about 10 μm or more and about 50 μm or less. The head 106 may be rotated when the photocatalyst 104 is brought in the proximity of the substrate WF, and the head 106 may be rotated after bringing the photocatalyst 104 in the proximity.

Next, the photocatalyst 104 is irradiated with the excitation light. By irradiating the photocatalyst 104 with the excitation light, the surface of the substrate WF can be processed by the active species generated by the photocatalyst reaction described above. As described above, in the substrate processing method using the photocatalyst according to this disclosure, since the substrate WF is removed preferentially from the projecting portion of the surface, the substrate WF can be planarized. Since the substrate WF can be processed in a state where the photocatalyst 104 and the substrate WF are contactless, the substrate WF is not mechanically damaged. By adjusting the above-described control factors, the substrate can be planarized at the atomic level.

When the processing of the substrate WF ends, the photocatalyst 104 and the substrate WF are separated. The irradiation with the excitation light is ended.

When the processing of one substrate WF ends, the conditioning of the photocatalyst 104 is performed as necessary. The arm 120 is driven, thus positioning the head 106 above the conditioner 150. Next, the head 106 is moved down, thus immersing the photocatalyst 104 in the conditioning liquid held in the conditioning tank 152. The photocatalyst 104 is irradiated with the excitation light in the state where the photocatalyst 104 is immersed in the conditioning liquid. At this time, the head 106 may be rotated. When the conditioner 150 includes the temperature controller 153, the temperature of the conditioning liquid may be controlled to become a predetermined temperature during the conditioning. During performing the conditioning of the photocatalyst 104, the catalyst sensor 154 may determine the activity power of the photocatalyst 104, thus determining the end of the conditioning.

While performing the conditioning of the photocatalyst 104, the substrate WF after the processing is moved from the table 102, and the substrate WF to be processed next is held onto the table 102. When the conditioning of the photocatalyst 104 ends, the processing of the new substrate WF on the table 102 is started.

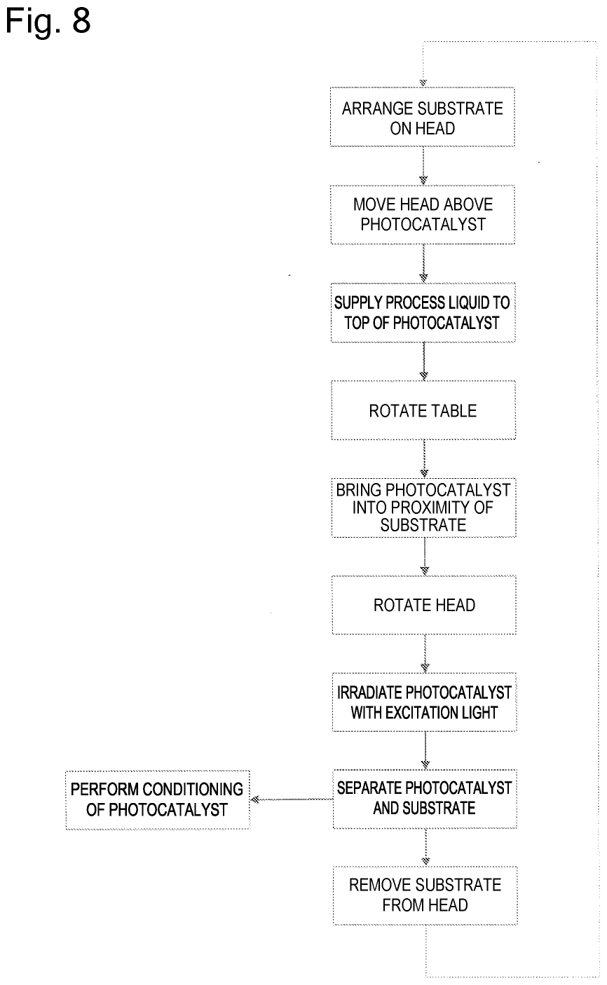

As one example, a substrate processing method using the substrate processing apparatus 10 described with FIGS. 3 to 5 will be described. FIG. 8 is a flowchart illustrating a substrate processing method according to one embodiment.

The substrate WF is held onto the head 206. Holding the substrate onto the head 206 can be performed by any method. For example, the head 206 is moved to a position at which the substrate WF is positioned, and the substrate WF can be held onto the head 206 by vacuum suction or the like. When the head 206 includes the temperature controller 207, the temperature of the substrate WF held onto the head 206 may be controlled to become a predetermined temperature by the temperature controller 207.

Next, the arm 220 is driven, thus moving the head 206 such that the head 206 is arranged above the photocatalyst 204 on the table 202.

Next, the process liquid is supplied to the top of the photocatalyst 204 on the table 202. The supply of the process liquid may be performed from the nozzle 208b disposed to the head 206, may be performed from the nozzle 208a outside the head 206, and may be performed from both nozzles 208a, 208b. At this time, the table 202 is rotated. When the substrate processing apparatus 10 includes the temperature controller 241, the supplied process liquid may be controlled to have a predetermined temperature by the temperature controller 241.

Next, the head 206 is moved toward the table 202 so as to bring the substrate WF in the proximity. The distance between the surface of the substrate WF and the surface of the photocatalyst 204 is determined from the lifespan of the active species generated by the photocatalyst reaction, the amount of the process liquid present between the photocatalyst and the substrate, and the like. For example, it is preferred to adjust the distance between the photocatalyst 204 and the substrate WF such that the distance between the surface of the substrate WF and the surface of the photocatalyst 204 becomes about 1 μm or more and about 500 μm or less. Furthermore, in consideration of the lifespan of the active species and the amount of the process liquid present between the photocatalyst and the substrate, the distance between the surface of the substrate WF and the surface of the photocatalyst 204 is more preferably 10 μm or more and 50 μm or less. The head 206 may be rotated when the substrate WF is brought in the proximity of the photocatalyst 204, and the head 206 may be rotated after bringing the substrate WF in the proximity.

Next, the photocatalyst 204 is irradiated with the excitation light. By irradiating the photocatalyst 204 with the excitation light, the surface of the substrate WF can be processed by the active species generated by the photocatalyst reaction described above. As described above, in the substrate processing method using the photocatalyst according to this disclosure, since the substrate WF is removed preferentially from the projecting portion of the surface, the substrate WF can be planarized. Since the substrate WF can be processed in a state where the photocatalyst 204 and the substrate WF are contactless, the substrate WF is not mechanically damaged. By adjusting the above-described control factors, the substrate can be planarized at the atomic level.

When the processing of the substrate WF ends, the photocatalyst 204 and the substrate WF are separated. The irradiation with the excitation light is ended.

When the processing of one substrate WF ends, the conditioning of the photocatalyst 204 is performed as necessary. The conditioning of the photocatalyst 204 can be performed by irradiating the photocatalyst 204 with the excitation light while supplying the conditioning liquid to the photocatalyst 204 on the table 202. The conditioning liquid can be the same as the process liquid in the processing of the substrate WF, and for example, the conditioning liquid may be supplied from the nozzle 208a. When the substrate processing apparatus 10 includes the temperature controller 241, the temperature of the process liquid as the conditioning liquid may be controlled to become a predetermined temperature. The table 202 may be rotated during the conditioning. During performing the conditioning of the photocatalyst 204, the catalyst sensor 254 may determine the activity power of the photocatalyst 204, thus determining the end of the conditioning.

While performing the conditioning of the photocatalyst 204, the substrate WF after the processing is removed from the head 206, and the substrate WF to be processed next is held onto the head 206. When the conditioning of the photocatalyst 204 ends, the processing of the new substrate WF held onto the head 206 is started.

In the substrate processing apparatus 10 in which the catalyst 204 is larger than the substrate WF in dimension as illustrated in FIG. 3 to FIG. 5, the conditioning can be simultaneously performed during the processing of the substrate WF. For example, during the processing of the substrate WF, by also irradiating a region of the catalyst 204 not in contact with the substrate WF with the excitation light, the conditioning can be performed to the region of the catalyst 204 not in contact with the substrate WF.

While the embodiments of the present invention have been described above based on some examples, the embodiments of the present invention are to facilitate understanding of the present invention without limiting the present invention. The present invention can be changed or improved without departing from the gist thereof, and of course, the equivalents of the present invention are included in the present invention. It is possible to appropriately combine or omit respective components according to claims and description in a range in which at least a part of the above-described problems can be solved, or a range in which at least a part of the effects can be exhibited.

From the above-described embodiments, at least the following technical ideas are obtained.

[Configuration 1] According to the configuration 1, a substrate processing apparatus is provided, and the substrate processing apparatus includes: a table for holding a substrate; a nozzle for supplying a process liquid to a surface to be processed of the substrate held onto the table; a head for holding a photocatalyst; a conditioner for conditioning the photocatalyst; a first moving mechanism for moving the head in a direction perpendicular to a surface of the table; and a second moving mechanism for moving the head between the table and the conditioner.

[Configuration 2] According to the configuration 2, in the substrate processing apparatus of the configuration 1, the conditioner includes a conditioning tank for holding the process liquid, and the conditioning tank has a dimension enough to accept the photocatalyst held onto the head.

[Configuration 3] According to the configuration 3, the substrate processing apparatus of the configuration 1 or the configuration 2 includes a first light source for emitting a light including a first wavelength for exciting the photocatalyst. The head includes: a base transparent to the first wavelength; the photocatalyst held onto a surface of the base; and an optical system for directing the light emitted from the first light source to the photocatalyst from a back surface of the base.

[Configuration 4] According to the configuration 4, in the substrate processing apparatus of the configuration 3, the optical system is configured to uniformly irradiate the photocatalyst held onto the surface of the base with the light.

[Configuration 5] According to the configuration 5, the substrate processing apparatus of the configuration 3 or the configuration 4 includes a light introduction path for introducing the light from the first light source to the head.

[Configuration 6] According to the configuration 6, in the substrate processing apparatus of the configuration 3 or the configuration 4, the head includes the first light source.

[Configuration 7] According to the configuration 7, in the substrate processing apparatus of any one of the configuration 1 to the configuration 6, the first light source includes a plurality of light sources, and the first light source has a plurality of regions and is configured to adjust an optical intensity irradiating the photocatalyst for each region.

[Configuration 8] According to the configuration 8, the substrate processing apparatus of any one of the configuration 1 to the configuration 7 includes a catalyst sensor for measuring an activity degree of the photocatalyst.

[Configuration 9] According to the configuration 9, in the substrate processing apparatus of the configuration 8, the catalyst sensor measures an electrical resistance of the photocatalyst.

[Configuration 10] According to the configuration 10, in the substrate processing apparatus of the configuration 8 or the configuration 9, the catalyst sensor is disposed at the conditioner.

[Configuration 11] According to the configuration 11, a substrate processing apparatus is provided, and the substrate processing apparatus includes: a table for holding a substrate; a nozzle for supplying a process liquid to a surface to be processed of the substrate held onto the table; a head for holding a photocatalyst; and a catalyst sensor for measuring an activity degree of the photocatalyst.

[Configuration 12] According to the configuration 12, in the substrate processing apparatus of the configuration 11, the catalyst sensor measures an electrical resistance of the photocatalyst.

[Configuration 13] According to the configuration 13, in the substrate processing apparatus of any one of the configuration 1 to the configuration 12, the head includes a process liquid flow passage for flowing the process liquid, and the nozzle is in fluid communication with the process liquid flow passage.

[Configuration 14] According to the configuration 14, the substrate processing apparatus of any one of the configuration 1 to the configuration 13 includes a temperature controller for adjusting a temperature of the process liquid.

[Configuration 15] According to the configuration 15, in the substrate processing apparatus of any one of the configuration 1 to the configuration 14, the table includes a temperature controller for adjusting a temperature of the substrate held onto the table.

[Configuration 16] According to the configuration 16, a substrate processing apparatus is provided, and the substrate processing apparatus includes: a table for holding a substrate; a nozzle for supplying a process liquid to a surface to be processed of the substrate held onto the table; a head for holding a photocatalyst; a first moving mechanism for moving the head in a direction perpendicular to a surface of the table; and a controller. The controller controls the first moving mechanism so as to bring the photocatalyst held onto the head in a proximity of the substrate held onto the table.

[Configuration 17] According to the configuration 17, the substrate processing apparatus of the configuration 16 includes a conditioner for conditioning the photocatalyst and a second moving mechanism for moving the head between the table and the conditioner. The controller controls the second moving mechanism to move the head to the conditioner when substrate processing ends.

[Configuration 18] According to the configuration 18, in the substrate processing apparatus of the configuration 17, the conditioner includes a conditioning tank for holding the process liquid, the substrate processing apparatus includes a first light source for emitting a light including a first wavelength for exciting the photocatalyst, the head includes: a base transparent to the first wavelength; the photocatalyst held onto a surface of the base; and an optical system for directing the light emitted from the first light source to the base from a back surface of the base, and the controller performs a control so as to move the head to the conditioner, immerse the photocatalyst in the process liquid held in the conditioning tank, and irradiate the photocatalyst with the light from the first light source.

[Configuration 19] According to the configuration 19, the substrate processing apparatus of any one of the configuration 16 to the configuration 18 includes a catalyst sensor for measuring an electrical resistance of the photocatalyst. The controller determines an activity degree of a catalytic activity of the photocatalyst based on the electrical resistance measured by the catalyst sensor.

[Configuration 20] According to the configuration 20, in the substrate processing apparatus of the configuration 19, the controller determines the activity degree of the catalytic activity of the photocatalyst based on the electrical resistance of the photocatalyst when the photocatalyst is irradiated with the light including the first wavelength and the electrical resistance of the photocatalyst when the photocatalyst is not irradiated with the light including the first wavelength.

[Configuration 21] According to the configuration 21, in the substrate processing apparatus of the configuration 19 or the configuration 20, the controller controls an intensity of the light emitted from the first light source during the substrate processing based on the determined activity degree of the photocatalyst.

[Configuration 22] According to the configuration 22, a substrate processing apparatus is provided, and the substrate processing apparatus includes: a table for holding a substrate; a nozzle for supplying a process liquid to a surface to be processed of the substrate held onto the table; a head for holding a photocatalyst, and a first light source for emitting a light including a first wavelength for exciting the photocatalyst. The head includes: a base transparent to the first wavelength; the photocatalyst held onto a surface of the base; and an optical system for directing the light emitted from the first light source to the base from a back surface of the base.

[Configuration 23] According to the configuration 23, in the substrate processing apparatus of the configuration 22, the optical system is configured to uniformly irradiate the photocatalyst held onto the surface of the base with the light.

[Configuration 24] According to the configuration 24, in the substrate processing apparatus of the configuration 22 or the configuration 23, the optical system includes at least one of a lens and a mirror.

[Configuration 25] According to the configuration 25, the substrate processing apparatus of any one of the configuration 22 to the configuration 24 includes a light introduction path for introducing the light from the first light source to the head.

[Configuration 26] According to the configuration 26, in the substrate processing apparatus of the configuration 25, the light introduction path includes an optical fiber.

[Configuration 27] According to the configuration 27, in the substrate processing apparatus of any one of the configuration 22 to the configuration 24, the head includes the first light source.

[Configuration 28] According to the configuration 28. in the substrate processing apparatus of any one of the configuration 22 to the configuration 27, the first light source includes a plurality of light sources, and the first light source has a plurality of regions and is configured to adjust an optical intensity for each region.

[Configuration 29] According to the configuration 29, in the substrate processing apparatus of any one of the configuration 22 to the configuration 28, the first wavelength is in ultraviolet region.

[Configuration 30] According to the configuration 30, in the substrate processing apparatus of any one of the configuration 1 to the configuration 29, the controller controls the first moving mechanism such that a distance between the photocatalyst held onto the head and the substrate held onto the table becomes 1 μm or more and 500 μm or less.

[Configuration 31] According to the configuration 31, a substrate processing apparatus is provided, and the substrate processing apparatus includes: a base having a surface configured to hold a photocatalyst, the base being transparent to a first wavelength; a first light source for emitting a light including a first wavelength for exciting the photocatalyst; an optical system for directing the light emitted from the first light source to the photocatalyst from a back surface of the base; a holding head for holding a substrate; a nozzle for supplying a process liquid to a top of the photocatalyst held onto a surface of the base; and a first moving mechanism for moving the holding head in a direction perpendicular to the surface of the base.

[Configuration 32] According to the configuration 32, in the substrate processing apparatus of the configuration 31, the optical system is configured to uniformly irradiate at least a part of a region of the photocatalyst held onto the surface of the base with the light.

[Configuration 33] According to the configuration 33, in the substrate processing apparatus of the configuration 31 or the configuration 32, the first light source includes a plurality of light sources.

[Configuration 34] According to the configuration 34, in the substrate processing apparatus of the configuration 33, the first light source has a plurality of regions and is configured to adjust an optical intensity irradiating the photocatalyst for each region.

[Configuration 35] According to the configuration 35, a substrate processing method is provided, and the substrate processing method includes: a step of bringing a substrate as a process target into a proximity of a photocatalyst in a presence of a process liquid; a step of irradiating the photocatalyst with an excitation light; and a step of conditioning the photocatalyst.

[Configuration 36] According to the configuration 36, in the substrate processing method described in the configuration 35, the step of conditioning includes a step of irradiating the photocatalyst with the excitation light in a state where the photocatalyst is in contact with a conditioning liquid.

[Configuration 37] According to the configuration 37, the substrate processing method of the configuration 35 or the configuration 36 includes a step of measuring an activity degree of the photocatalyst.

### REFERENCE SIGNS LIST

10 . . . substrate processing apparatus

102 . . . table

103 . . . temperature controller

104 . . . photocatalyst

106 . . . head

108 . . . nozzle

114 . . . drive shaft

118 . . . shaft

120 . . . arm

126 . . . shaft

130 . . . head body

132 . . . base

134 . . . light source

136 . . . light introduction path

138 . . . optical system

140 . . . process liquid supply source

141 . . . temperature controller

146 . . . power source

150 . . . conditioner

152 . . . conditioning tank

154 . . . catalyst sensor

156 . . . probe

202 . . . table

204 . . . photocatalyst

206 . . . head

207 . . . temperature controller

208 . . . nozzle

214 . . . drive shaft

218 . . . shaft

220 . . . arm

226 . . . shaft

232 . . . base

234 . . . light source

235 . . . support table

238 . . . optical system

240 . . . process liquid supply source

241 . . . temperature controller

246 . . . power source

254 . . . catalyst sensor

256 . . . probe

WF . . . substrate

1. A substrate processing apparatus comprising:
a table for holding a substrate;
a nozzle for supplying a process liquid to a surface to be processed of the substrate held onto the table;
a head for holding a photocatalyst;
a conditioner for conditioning the photocatalyst;
a first moving mechanism for moving the head in a direction perpendicular to a surface of the table; and
a second moving mechanism for moving the head between the table and the conditioner.

2. The substrate processing apparatus according to claim 1, wherein
the conditioner includes a conditioning tank for holding the process liquid, and
the conditioning tank has a dimension enough to accept the photocatalyst held onto the head.

3. The substrate processing apparatus according to claim 1, comprising
a first light source for emitting a light including a first wavelength for exciting the photocatalyst wherein
the head includes:
a base transparent to the first wavelength;
the photocatalyst held onto a surface of the base; and
an optical system for directing the light emitted from the first light source to the photocatalyst from a back surface of the base.

4. The substrate processing apparatus according to claim 3, wherein
the optical system is configured to uniformly irradiate the photocatalyst held onto the surface of the base with the light.

5. The substrate processing apparatus according to claim 3, comprising
a light introduction path for introducing the light from the first light source to the head.

6. The substrate processing apparatus according to claim 3, wherein
the head includes the first light source.

7. The substrate processing apparatus according to claim 1, wherein
the first light source includes a plurality of light sources, and the first light source has a plurality of regions and is configured to adjust an optical intensity irradiating the photocatalyst for each region.

8. The substrate processing apparatus according to claim 1, comprising
a catalyst sensor for measuring an activity degree of the photocatalyst.

9. The substrate processing apparatus according to claim 8, wherein
the catalyst sensor measures an electrical resistance of the photocatalyst.

10. The substrate processing apparatus according to claim 8, wherein
the catalyst sensor is disposed at the conditioner.

11. A substrate processing apparatus comprising:
a table for holding a substrate;
a nozzle for supplying a process liquid to a surface to be processed of the substrate held onto the table;
a head for holding a photocatalyst; and
a catalyst sensor for measuring an activity degree of the photocatalyst.

12. The substrate processing apparatus according to claim 11, wherein
the catalyst sensor measures an electrical resistance of the photocatalyst.

13. The substrate processing apparatus according to claim 1, wherein
the head includes a process liquid flow passage for flowing the process liquid, and
the nozzle is in fluid communication with the process liquid flow passage.

14. The substrate processing apparatus according to claim 1, comprising
a temperature controller for adjusting a temperature of the process liquid.

15. The substrate processing apparatus according to claim 1, wherein
the table includes a temperature controller for adjusting a temperature of the substrate held onto the table.

16-37. (canceled)
